(19) United States
(12) Patent Application Publication
(10) Pub. No.: US 2024/0318314 A1
(43) Pub. Date: Sep. 26, 2024

(54) SUBSTRATE SUPPORT DEVICE

(71) Applicant: SAMSUNG ELECTRONICS CO., LTD., Suwon-si (KR)

(72) Inventors: Yonjoo KANG, Suwon-si (KR); Yunjae Lee, Suwon-si (KR); Junhyung Kim, Suwon-si (KR); Youngbok Lee, Suwon-si (KR); Sangchul Han, Suwon-si (KR); Minsung Kim, Suwon-si (KR); Inhwan Park, Suwon-si (KR); Sangyeon Oh, Suwon-si (KR)

(21) Appl. No.: 18/609,067

(22) Filed: Mar. 19, 2024

(30) Foreign Application Priority Data
Mar. 24, 2023 (KR) 10-2023-0039249
May 18, 2023 (KR) 10-2023-0064562

(51) Int. Cl. C23C 16/458; C23C 16/46

(52) U.S. Cl. CPC C23C 16/4586; C23C 16/46

(57) ABSTRACT

A substrate support device includes a chuck plate, a shaft connected to a center lower end of the chuck plate, a heater unit provided inside the chuck plate, an electrode unit provided inside the chuck plate, and provided on the heater unit, a jumper unit provided inside the chuck plate, arranged between the electrode unit and the heater unit, and electrically connected to the electrode unit to supply power to the electrode unit, and a power control unit, wherein the electrode unit includes a center electrode and a first electrode arranged in a ring shape around the center electrode, wherein the jumper unit includes a first jumper connected to the first electrode and a center jumper connected to the center electrode, and wherein the first jumper includes a first connection jumper, and a first inclined jumper electrically connecting the first jumper.

### CROSS-REFERENCE TO RELATED APPLICATIONS

This application is based on and claims priority under 35 U.S.C. § 119 to Korean Patent Application Nos. 10-2023-0039249, filed on Mar. 24, 2023, and 10-2023-0064562, filed on May 18, 2023, in the Korean Intellectual Property office, the disclosures of which are incorporated by reference herein in their entireties.

### BACKGROUND

### 1. Field

Embodiments relate to a substrate support device, and more particularly, to a substrate support device including a heater unit.

### 2. Description of the Related Art

In general, semiconductor devices or display devices are manufactured in a method of sequentially stacking a plurality of thin layers, including dielectric layers and metal layers, and patterning them. These thin layers may be sequentially deposited on a substrate by using, e.g., a chemical vapor deposition (CVD) or physical vapor deposition (PVD) process. CVD or PVD devices may include heater units for heating and an electrode inside a chuck plate for applying a chucking force to attach the substrate to the chuck plate.

### SUMMARY

According to aspects of embodiments, there is provided a substrate support device including a chuck plate of a disk shape capable of supporting a substrate on an upper surface thereof, a shaft connected to a center lower end of the chuck plate to support the chuck plate, a heater unit provided inside the chuck plate, an electrode unit provided inside the chuck plate, and provided on the heater unit, a jumper unit provided inside the chuck plate, arranged between the electrode unit and the heater unit, and electrically connected to the electrode unit to supply power to the electrode unit, and a power control unit connected to the jumper unit via a wire, and configured to supply and control power supplied to the electrode unit via the wire, wherein the electrode unit includes a center electrode and a first electrode arranged in a ring shape around the center electrode, wherein the jumper unit includes a first jumper connected to the first electrode, and a center jumper connected to the center electrode, and wherein the first jumper includes a first connection jumper and a first inclined jumper electrically connecting the first jumper to the first electrode and being closer to an upper surface of the chuck plate away from a center of the chuck plate in a radial direction of the chuck plate.

In addition, according to other aspects of embodiments, there is provided a substrate support device including a chuck plate of a disk shape capable of supporting a substrate on an upper surface thereof, a shaft connected to a center lower end of the chuck plate to support the chuck plate, a heater unit provided inside the chuck plate, an electrode unit provided inside the chuck plate, and provided on the heater unit, a jumper unit provided inside the chuck plate, arranged between the electrode unit and the heater unit, and electrically connected to the electrode unit to supply power, and a power control unit connected to the jumper unit via a wire, and configured to supply and control power supplied to the electrode unit via the wire, wherein the electrode unit includes a first electrode, N (N is a natural number equal to or greater than 3) electrodes, and a center electrode, which face from a periphery of the chuck plate to a center of the chuck plate, wherein the jumper unit includes a first jumper connected to the first electrode, N jumpers respectively connected to the N electrodes, and a center jumper connected to the center electrode, wherein the N electrodes are provided between the first electrode and the center electrode, and the first electrode and the N electrodes are arranged apart from each other in a concentric circular band shape from the center of the chuck plate, wherein the first jumper includes a first connection jumper and a first inclined jumper electrically connecting the first connection jumper to the first electrode and being closer to the upper surface of the chuck plate away from the center of the chuck plate in the radial direction of the chuck plate, and wherein the N jumpers respectively include N connection jumpers, and N inclined jumpers respectively and electrically connect the N connection jumpers to the N electrodes, and being closer to the upper surface of the chuck plate away from the center of the chuck plate in the radial direction of the chuck plate.

In addition, according to yet other aspects of embodiments, there is provided a substrate support device including a chuck plate of a disk shape capable of supporting a substrate on an upper surface thereof, a shaft connected to a center lower end of the chuck plate to support the chuck plate, a heater unit provided inside the chuck plate, an electrode unit provided inside the chuck plate, and provided on the heater unit, a jumper unit provided inside the chuck plate, arranged between the electrode unit and the heater unit, and electrically connected to the electrode unit to supply power to the electrode unit, and a power control unit connected to the jumper unit via a wire, and configured to supply and control power supplied to the electrode unit via the wire, wherein the electrode unit includes a first electrode, a second electrode, a third electrode, and a center electrode, which face from a periphery of the chuck plate to a center of the chuck plate, wherein the jumper unit includes a first jumper connected to the first electrode, a second jumper connected to the second electrode, a third electrode connected to the third electrode, and a center jumper connected to the center electrode, wherein the second electrode and the third electrode are provided between the first electrode and the center electrode, and the first electrode, the second electrode, and the third electrode is arranged apart from each other in a concentric circular band shape from the center of the chuck plate, wherein the first jumper includes a first connection jumper and a first inclined jumper electrically connecting the first connection jumper to the first electrode and being closer to the upper surface of the chuck plate away from the center of the chuck plate in the radial direction of the chuck plate, wherein the second jumper includes a second connection jumper and a second inclined jumper electrically connecting the second connection jumper to the second electrode and being closer to the upper surface of the chuck plate away from the center of the chuck plate in the radial direction of the chuck plate, wherein the third jumper includes a third connection jumper and a third inclined jumper electrically connecting the third connection jumper to the third electrode and being closer to the upper surface of the chuck plate away from the center of the chuck plate in the radial direction of the chuck plate, wherein the first connection jumper, the second connection jumper, the third connection jumper are provided on a flat surface in parallel with the upper surface of the chuck plate, wherein an angle formed between the first inclined jumper and the first connection jumper is an obtuse angle, wherein an angle formed between the second inclined jumper and the second connection jumper is an obtuse angle, wherein an angle formed between the third inclined jumper and the third connection jumper is an obtuse angle, wherein the power control unit is configured to control power supplied to each of the first electrode, the second electrode, the third electrode, and the center electrode, and wherein the first electrode is arranged in a range of 145 to 155 mm, the second electrode is arranged in a range of 140 mm to 145 mm, and the third electrode is arranged in a range of 135 mm to less than 140 mm.

### BRIEF DESCRIPTION OF THE DRAWINGS

Features will become apparent to those of skill in the art by describing in detail exemplary embodiments with reference to the attached drawings, in which:

FIG. 1 is a cross-sectional view of a substrate support device according to an embodiment;

FIG. 2 is an enlarged cross-sectional view of a portion of a substrate support device, according to an embodiment;

FIG. 3 is a graph illustrating a reaction force acting on a substrate arranged on a substrate support device, according to an embodiment;

FIG. 4 is a schematic diagram of an electrode unit, a power control unit, and a jumper unit of a substrate support device, according to an embodiment;

FIG. 5 is an enlarged cross-sectional view of a portion of a substrate support device, according to an embodiment;

FIG. 6A is a plan view of a substrate support device according to an embodiment;

FIG. 6B is a plan view of a substrate support device according to an embodiment;

FIG. 7A is a plan view of a substrate support device according to an embodiment;

FIG. 7B is a plan view of a substrate support device according to an embodiment;

FIG. 8 is an enlarged cross-sectional view of a portion of a substrate support device, according to an embodiment;

FIG. 9 is an enlarged cross-sectional view of a portion of a substrate support device, according to an embodiment; and

FIG. 10 illustrates simulation results of substrate support devices according to an embodiment.

### DETAILED DESCRIPTION

Hereinafter, example embodiments are described in detail with reference to the accompanying drawings. Identical reference numerals are used for the same constituent elements in the drawings, and duplicate descriptions thereof are omitted.

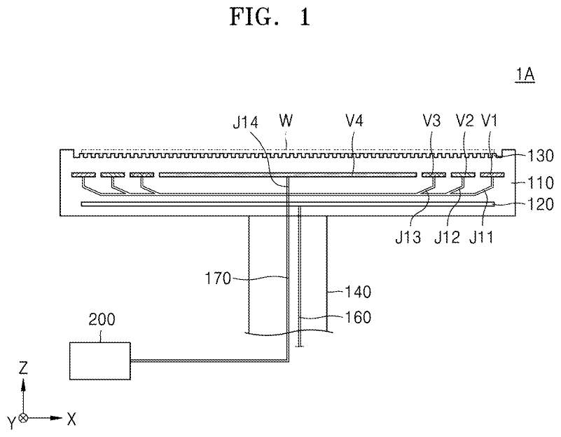

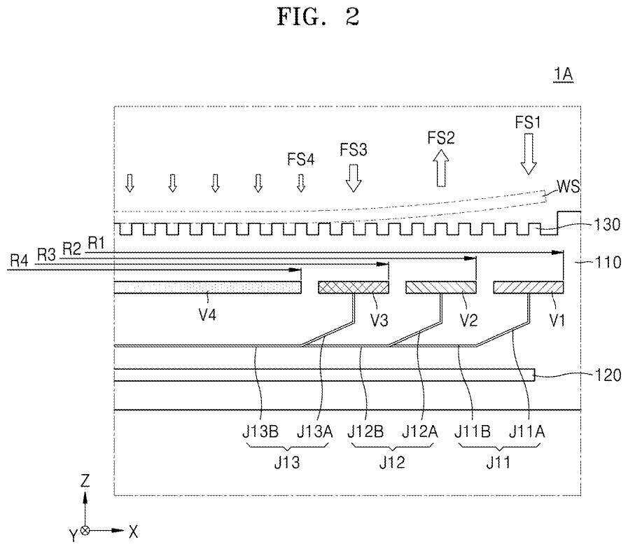

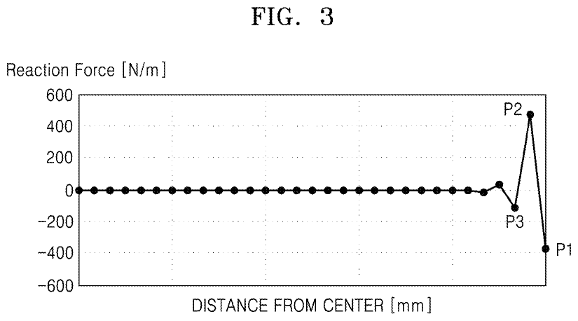

FIG. 1 is a cross-sectional view illustrating a substrate support device 1A according to an embodiment. FIG. 2 is an enlarged cross-sectional view of a portion of the substrate support device 1A in FIG. 1. FIG. 3 is a graph illustrating a reaction force acting on a substrate W arranged on the substrate support device 1A.

Referring to FIG. 1, the substrate support device 1A may include a chuck plate 110, a heater 120 provided inside the chuck plate 110, an electrode unit (e.g., electrode structure) provided inside the chuck plate 110 and arranged on the heater 120, a bump unit 130 (e.g., a bump structure) provided on an upper surface of the chuck plate 110, a shaft 140 arranged at a center of a lower surface of the chuck plate 110 and supporting the chuck plate 110, a heater wire 160 connecting the heater 120 to an external power source, a power control unit 200 (e.g., a power controller), and electrode wires 170 connecting the power control unit 200 to jumpers included in a jumper unit (e.g., a jumper structure).

The substrate support device 1A according to an embodiment may be used in a chemical vapor deposition (CVD) process. The electrode unit may be included in the chuck plate 110 or may be connected to a direct current (DC) generator provided separately, and may apply a chucking force to the substrate W to fix the substrate W. The heater 120 may supply heat to process a substrate treatment by controlling the temperatures of the plasma and the substrate W placed on the chuck plate 110. The chuck plate 110 may include a material including aluminum nitride (AlN) to perform a process under high temperature conditions. In addition, the substrate support device 1A according to an embodiment may have a process temperature (i.e., a temperature at which a process is performed) of 400° C. or higher and 800° C. or lower.

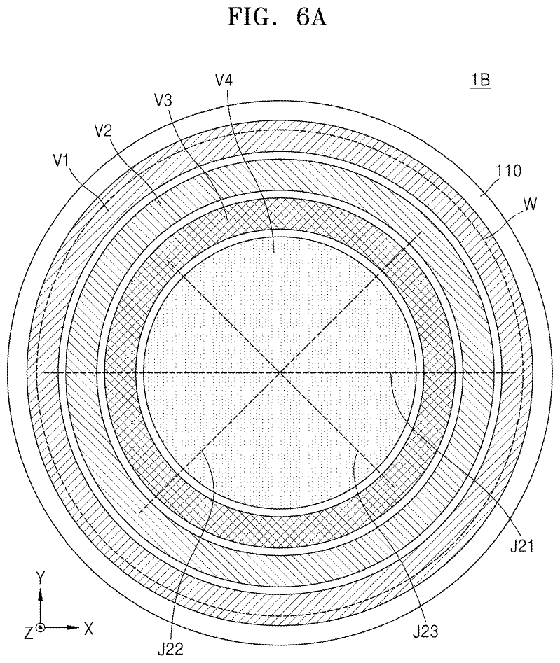

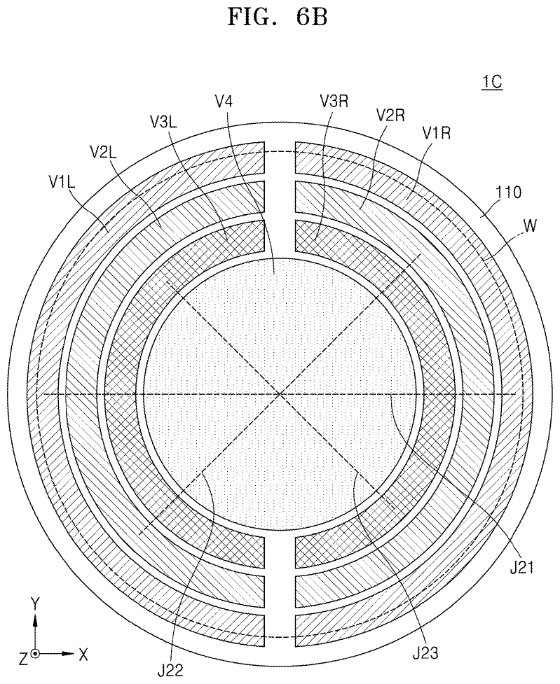

Referring to FIGS. 1 and 2, the electrode unit may include a first electrode V1, a second electrode V2, a third electrode V3, and a center electrode V4. The first electrode V1, the second electrode V2, the third electrode V3, and the center electrode V4 may be arranged on the same horizontal plane in parallel with the upper surface of the chuck plate 110. In other words, the first electrode V1, the second electrode V2, the third electrode V3, and the center electrode V4 may be arranged on a horizontal plane in parallel with an X-Y plane simultaneously in parallel with a first horizontal direction (X-axis direction) and a second horizontal direction (Y-axis direction) perpendicular to the first horizontal direction. Referring to FIG. 6A to be described below, the first electrode V1, the second electrode V2, and the third electrode V3 may be provided in a shape of a concentric circular band around the center electrode V4, e.g., the first to third electrodes V1 to V3 may be concentric circular bands around the center electrode V4. The first electrode V1, the second electrode V2, the third electrode V3, and the center electrode V4 may be arranged to be horizontally, e.g., radially, spaced apart from each other at particular intervals.

For example, as illustrated in FIG. 6A, each of the first electrode V1, the second electrode V2, and the third electrode V3 may have one connected circular band shape, e.g., a single continuous band surrounding an entire perimeter of the center electrode V4. In another example, as illustrated in FIG. 6B, a plurality of arc-shaped partial electrodes with partially disconnected portions may individually form each of the first electrode V1, the second electrode V2, and the third electrode V3. In other words, as illustrated in FIG. 6B, each of the first electrode V1, the second electrode V2, and the third electrode V3 may include two or more arc-shaped partial electrodes arranged around the center electrode V4, e.g., with the same center, due to the partial cut of the circular band shape.

Referring back to FIGS. 1 and 2, each component of the electrode unit may be electrically connected to the electrode wires 170 via a corresponding jumper. The electrode wires 170 may include a plurality of wires. Each of the plurality of wires included in the electrode wires 170 may be electrically connected to each jumper included in the jumper unit (e.g., the jumper unit may include a first jumper J11, a second jumper J12, a third jumper J13, and a fourth jumper J14 respectively connected to the first electrode V1, the second electrode V2, the third electrode V3, and the center electrode V4). Each of the wires included in the electrode wires 170 may be connected to the power control unit 200. Each of the wires included in the electrode wires 170 may connect each jumper to the power control unit 200. The power control unit 200 may individually control power supplied to the first electrode V1, the second electrode V2, the third electrode V3, and the center electrode V4 included in the electrode unit.

The first jumper J11 may be connected to the first electrode V1. The first jumper J11 may include a first inclined jumper J11A and a first connection jumper J11B. The first inclined jumper J11A may electrically connect a bottom surface of the first electrode V1 to the first connection jumper J11B. The first connection jumper J11B may electrically connect one wire of the electrode wires 170 to the first inclined jumper J11A. The first inclined jumper J11A may have a shape of becoming closer to the upper surface of the chuck plate 110 away from the center of the chuck plate 110 in a radial direction of the chuck plate 110 (e.g., a shape of the first inclined jumper J11A may have a first end extending toward the center of the chuck plate 110 (e.g., and contacting the first connection jumper J11B) and a second end extending away from the center of the chuck plate 110 toward the upper surface of the chuck plate 110 in a radial direction of the chuck plate 110 to contact the first electrode V1). In example embodiments, the radial direction refers to a direction toward an outer diameter of the chuck plate 110 with respect to the center of the chuck plate 110.

As illustrated in FIG. 2, at a portion of the first inclined jumper J11A connected to the first connection jumper J11B, an angle between the first connection jumper J11B and the first inclined jumper J11A may be an obtuse angle. For example, an angle formed by the first connection jumper J11B and the first inclined jumper J11A may be 100° or more and 150° or less.

For example, as illustrated in FIG. 2, the first inclined jumper J11A may include a vertical portion and an inclined straight (e.g., linear) portion, e.g., a vertical portion extending vertically toward the heater 120 and an inclined straight portion extending from the vertical portion at an oblique angle toward the heater 120. In another example, the inclined straight portion of the first inclined jumper J11A may extend to be directly connected to the first electrode V1 (i.e., without the vertical portion). For example, as illustrated in FIG. 2, the vertical portion of the first inclined jumper J11A perpendicular to the horizontal plane in parallel with the upper surface of the chuck plate 110 may extend from the inclined straight portion of the first inclined jumper J11A, and the vertical portion of the first inclined jumper J11A may be connected to the first electrode V1.

The second jumper J12 may be connected to the second electrode V2. The second jumper J12 may include a second inclined jumper J12A and a second connection jumper J12B. The second inclined jumper J12A may electrically connect a lower surface of the second electrode V2 to the second connection jumper J12B. The second connection jumper J12B may electrically connect one wire of the electrode wires 170 to the second inclined jumper J12A. The second inclined jumper J12A may have a same or substantially same shape as that of the first jumper J11, i.e., a shape of becoming closer to the upper surface of the chuck plate 110 away from the center of the chuck plate 110 in a radial direction of the chuck plate 110.

As illustrated in FIG. 2, at a portion of the second inclined jumper J12A connected to the second connection jumper J12B, an angle between the second connection jumper J11B and the second inclined jumper J11A may be an obtuse angle. For example, an angle formed by the second connection jumper J12B and the second inclined jumper J12A may be 100° or greater and 150° or less.

The second inclined jumper J12A may include an inclined straight portion and a vertical portion. Unlike FIG. 2, the inclined straight portion of the second inclined jumper J12A may extend to be directly connected to the second electrode V2. For example, as illustrated in FIG. 2, the vertical portion of the second inclined jumper J12A perpendicular to the horizontal plane in parallel with the upper surface of the chuck plate 110 may extend from the inclined straight portion of the second inclined jumper J12A and may be connected to the second electrode V2.

The third jumper J13 may be connected to the third electrode V3. The third jumper J13 may include a third inclined jumper J13A and a third connection jumper J13B. The third inclined jumper J13A may electrically connect a bottom surface of the third electrode V3 to the third connection jumper J13B. The third connection jumper J13B may electrically connect one wire of the electrode wires 170 to the third inclined jumper J13A. The third inclined jumper J13A may have a same or substantially same shape as that of the first jumper J11, i.e., a shape of becoming closer to the upper surface of the chuck plate 110 away from the center of the chuck plate 110 in the radial direction of the chuck plate 110.

As illustrated in FIG. 2, at a portion of the third inclined jumper J13A connected to the third connection jumper J13B, an angle between the third connection jumper J13B and the third inclined jumper J13A may be an obtuse angle. For example, an angle formed by the third connection jumper J13B and the third inclined jumper J13A may be 100° or greater and 150° or less.

The third inclined jumper J13A may include an inclined straight portion and a vertical portion. Unlike FIG. 2, the inclined straight portion of the third inclined jumper J13A may extend to be directly connected to the third electrode V3. For example, as illustrated in FIG. 3, the vertical portion of the third inclined jumper J13A perpendicular to the horizontal plane in parallel with the upper surface of the chuck plate 110 may extend from the inclined straight portion of the third inclined jumper J13A and may be connected to the third electrode V3.

The fourth jumper J14 may be connected to the center electrode V4. The fourth jumper J14 may electrically connect a bottom surface of the center electrode V4 to one wire of the electrode wires 170, e.g., the fourth jumper J14 may include a vertical portion extending through the chuck plate 110.

An outer diameter of the first electrode V1 refers to a circumference of the first electrode V1 having a farther radial distance from the center of the chuck plate 110. An inner diameter of the first electrode V1 refers to a circumference of the first electrode V1 having a shorter radial distance from the center of the chuck plate 110. The first electrode V1 may be arranged between a first radial distance R1 and a second radial distance R2 from the center of the chuck plate 110. Likewise, the second electrode V2 may be arranged between the second radial distance R2 and a third radial distance R3 from the center of the chuck plate 110. The third electrode V3 may be arranged between the third radial distance R3 and a fourth radial distance R4 from the center of the chuck plate 110.

In an embodiment, the first radial distance R1 may be 155 mm. The second radial distance R2 may be 145 mm. The third radial distance R3 may be 140 mm. The fourth radial distance R4 may be 135 mm. Thus, the first electrode V1 may be arranged in a range of 145 mm or more and 155 mm or less from the center of the chuck plate 110, the second electrode V2 may be arranged in a range of 140 mm to 145 mm from the center of the chuck plate 110, and the third electrode V3 may be arranged in a range of 135 mm to less than 140 mm from the center of the chuck plate 110. The radius of the substrate W may be 150 mm. In example embodiments, the substrate W may refer to a wafer.

In a substrate W treatment process by using the substrate support device 1A according to an embodiment, the chuck plate 110 may be heated to a high temperature by the heater 120. Heat may be transferred to the substrate W due to the temperature increase of the chuck plate 110. The substrate W may be heated due to the chuck plate 110 being at a high temperature. When the substrate W is heated, warpage of a smile or a cry-shape may be potentially generated on the substrate W. Smile warpage refers to a warpage having a downward convex shape (e.g., a dashed line illustrating a smile substrate WS in FIG. 2), and a cry warpage refers to warpage of an upward convex shape.

As illustrated in FIG. 2, for a smooth substrate treatment process of the smile substrate WS (i.e., where a smile warpage has occurred), an electro-static chucking force capable of suppressing the warpage may be implemented. That is, a chucking force may be generated by an electrostatic force applied to the smile substrate WS by the power supplied (e.g., independently) to the first electrode V1, the second electrode V2, the third electrode V3, and the center electrode V4 in order to prevent or substantially minimize any warpage (e.g., edge curving) of the substrate. The warpage of the substrate may increase as a distance from the outer diameter of the substrate W decreases (e.g., so a larger warpage may be generated at an outer edge of the substrate). When the warpage of the substrate is the smile warpage, chucking forces for offsetting the smile warpage generated by the first electrode V1, the second electrode V2, the third electrode V3, and the center electrode V4 may be different from each other. Different chucking forces of the first electrode V1, the second electrode V2, the third electrode V3, and the center electrode V4 may be generated, e.g., adjusted, by using the power control unit 200 connected to the electrode unit.

Referring to FIG. 3, the substrate W having a radius of 150 mm is used as an object, and the graph illustrates a result deduced by simulation of a reacting force per unit length (hereinafter, a reacting force) applied to the substrate W by the chuck plate 110 according to radial direction positions, when warpage estimated to be generated in the substrate treatment process at a high temperature is offset by the chucking force of the electrode unit. Conditions of the simulation are 0.675 mm thickness of the substrate W, 10e-6/K thermal expansion coefficient of the substrate W, 0.1 mm film thickness of the upper surface of the substrate W, and 2.5e-6/K thermal expansion coefficient of the film.

A first point P1 refers to a reaction force that the substrate W receives from the chuck plate 110 at a point where the radial distance from the center of the chuck plate 110 is 150 mm (i.e., a maximal distance from the center of the substrate W which is overlapped by the first electrode V1). The magnitude of the reaction force at the first point P1 may be 369 N/m, which refers to the chucking force applied by the first electrode V1 required to prevent warpage of the substrate W.

A second point P2 refers to a reaction force that the substrate W receives from the chuck plate 110 at a point where the radial distance from the center of the chuck plate 110 is 145 mm (i.e., a point overlapped by the second electrode V2). A vertical axis value of the second point P2 is 472 N/m, and the second point P2 may be a region where the maximum support force is applied to the substrate W. A third point P3 refers to a reaction force that the substrate W receives from the chuck plate 110 at a point where the radial distance from the center of the chuck plate 110 is 140 mm (i.e., a point overlapped by the third electrode V3). The vertical axis value of the third point P3 may be 115.9 N/m, and the magnitude of the reaction force applied to the substrate W may be less than those of the second point P2 and the first point P1, but the third point P3 may correspond to a section where a certain level of reaction force substantially starts to act on the substrate W to offset the warpage of the substrate W.

The reaction forces at the first point P1, the second point P2, and the third point P3 in the graph of FIG. 3 may correspond to a first smile reaction force FS1, a second smile reaction force FS2, and a third smile reaction force FS3, respectively. In other words, thicker arrows in FIG. 2 indicate that a pulling force is applied on the substrate W downwardly at the first point P1 and the third point P3 as the chucking force, and the substrate W receives a reaction force from the chuck plate 110 near the second point P2 due to the pulling force around the second point P2 even without applying a pulling force on the substrate W by using the second electrode V2. A fourth smile reaction force FS4 may be generated by the center electrode V4, and the chucking force may act on the substrate W at a level sufficient for the substrate W to be fixed on the chuck plate 110.

Referring to the simulation result in FIG. 3, a high chucking force may be required from a radial distance of 130 mm or more, and a plurality of electrodes may be required to apply the chucking force required for each section of the radial distance in the corresponding range to the substrate W. For example, as described above, in the substrate support device 1A according to an embodiment, the first electrode V1 may be arranged at a radial distance of a range of 145 mm to 155 mm, the second electrode V2 may be arranged at a radial distance of a range of 140 mm to 145 mm, and the third electrode V3 may be arranged at a radial distance of a range of 135 mm to 140 mm. Accordingly, the chucking force applied to the substrate W may be optimized according to the number of electrodes arranged and the ranges in which the electrodes are arranged. By providing a chucking force of a required level to the substrate W, it may be possible to minimize warpage of the substrate W and at the same time, adjust the chuck plate 110 not to exert excessively a reaction force, which is applied to the substrate W by the chuck plate 110, and generated by the chucking force applied to the substrate W. Accordingly, damage that may occur on a lower surface of the substrate W supported by the chuck plate 110 due to an excessive reaction force may be prevented or substantially reduced. Thus, treatment efficiency and yield of the substrate W may be improved.

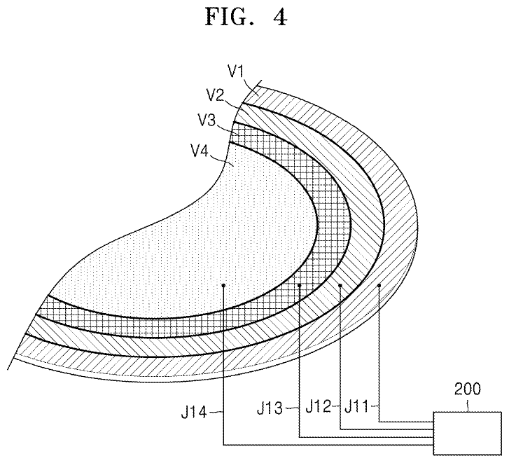

FIG. 4 is a schematic diagram of the electrode unit, the power control unit 200, and the jumper unit of the substrate support device 1A, according to an embodiment.

For example, referring to FIG. 4, power may be applied to the first electrode V1 and the third electrode V3 respectively corresponding to the first point P1 and the third point P3 (in FIG. 3). The power control unit 200 may apply power so that the first electrode V1 and the third electrode V3 apply a sufficient pulling force to the substrate W arranged on the chuck plate 110. In addition, as described above, because a pulling force at the first point P1 greater than that at the third point P3 is required, the power control unit 200 may apply power, greater than power applied to the third electrode V3, to the first electrode V1, which applies a chucking force at the first point P1. In other words, the power control unit 200 may individually apply power optimized to reduce damage of the substrate W depending on the degree of warpage of the substrate W to each electrode included in the electrode unit. Thus, instead of manufacturing a substrate support device provided with a separate electrode according to the substrate W and process conditions, in which the substrate W is processed, the power applied to each electrode of the power control unit 200 may be adjusted to cope with various types of warpage and various strengths of warpage generated in the substrate W.

For example, unlike the smile warpage of the substrate W described with reference to FIG. 2, the cry warpage may occur in the substrate W. In this case, by increasing the chucking force applied to the substrate W by increasing power applied to the center electrode V4, and adjusting power applied to the first electrode V1, the second electrode V2, and the third electrode V3, the power control unit 200 may offset the cry warpage while decreasing damage of the substrate W where the cry warpage occurs. In other words, as described above, by adjusting power applied to each electrode, the power control unit 200 may cope with various types of warpage and various strengths of warpage generated in the substrate W.

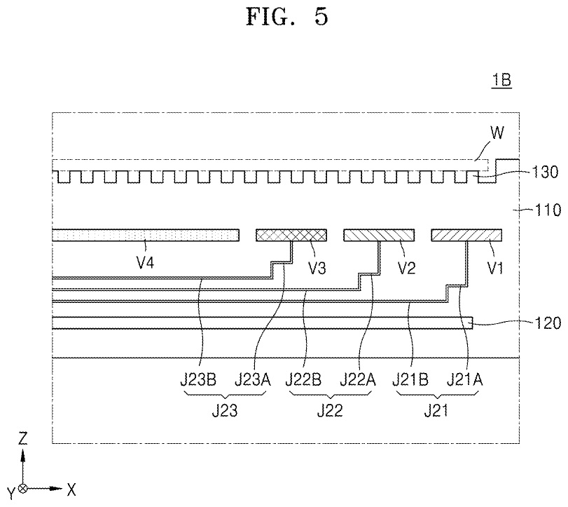

FIG. 5 is an enlarged cross-sectional view of a portion of a substrate support device 1B, according to an embodiment. FIG. 6A is a plan view of the substrate support device 1B according to an embodiment. FIG. 6B is a plan view of a substrate support device 1C according to an embodiment. Duplicate descriptions given above are omitted.

Referring to FIG. 5, a first jumper J21 may be connected to the first electrode V1. The first jumper J21 may include a first inclined jumper J21A and a first connection jumper J21B. The first inclined jumper J21A may electrically connect the bottom surface of the first electrode V1 to the first connection jumper J21B, e.g., the first connection jumper J21B may extend horizontally in parallel to the heater 120. The first connection jumper J21B may electrically connect one wire of the electrode wires 170 to the first inclined jumper J21A. The first inclined jumper J21A may have a shape of becoming closer to the upper surface of the chuck plate 110 away from the center of the chuck plate 110 in a radial direction of the chuck plate 110. The first inclined jumper J21A may be referred to as a first step jumper. The first inclined jumper J21A may extend perpendicularly to the first connection jumper J21B. In example embodiments, a portion forming a vertical section on the jumper may be referred to as a bent section. As illustrated in FIG. 5, the first inclined jumper J21A may include three bent sections, e.g., the first inclined jumper J21A may include two vertical sections connected to each other by a horizontal section to define a step shape.

Similar to the first jumper J21, a second jumper J22 may include a second inclined jumper J22A and a second connection jumper J22B, and a third jumper J23 may include a third inclined jumper J23A and a third connection jumper J23B. The second inclined jumper J22A may extend perpendicularly to the second connection jumper J22B. As illustrated in FIG. 5, the second inclined jumper J22A may include three bent sections, e.g., the second inclined jumper J22A may include two vertical sections connected to each other by a horizontal section to define a step shape. The third inclined jumper J23A may extend perpendicularly to the third connection jumper J23B. As illustrated in FIG. 5, the third inclined jumper J23A may include three bent sections, e.g., the third inclined jumper J23A may include two vertical sections connected to each other by a horizontal section to define a step shape.

The substrate support device 1A according to embodiments of FIGS. 1 and 2 may include the first connection jumper J11B, the second connection jumper J12B, and the third connection jumper J13B provided on one plane in parallel with the upper surface of the chuck plate 110. Unlike as illustrated FIGS. 1 and 2, the substrate support device 1B of FIG. 5 may include the first connection jumper J21B, the second connection jumper J22B, and the third connection jumper J23B provided on a plane in parallel with the chuck plate 110 but may include the first connection jumper J21B, the second connection jumper J22B, and the third connection jumper J23B respectively provided on different planes. In this manner, by using the substrate support device 1B including connection jumpers provided on different planes, an arrangement of a plurality of electrodes and an arrangement of a plurality of jumpers corresponding to the plurality of electrodes may be easily implemented inside the chuck plate 110.

Referring to FIG. 6A, each of the first jumper J21, the second jumper J22, and the third jumper J23 indicated by dashed lines may be configured to radially extend in different directions with reference to the center of the chuck plate 110. At the same time, the first connection jumper J21B, the second connection jumper J22B, and the third connection jumper J23B may be provided on a plane in parallel with the chuck plate 110, but the first connection jumper J21B, the second connection jumper J22B, and the third connection jumper J23B may be respectively provided on different planes. Unlike as illustrated in FIG. 6A, the first jumper J21, the second jumper J22, and the third jumper J23 may extend away from the center of the chuck plate 110 toward the outer diameter of the chuck plate 110 without passing through the center of the chuck plate 110. By arranging the radial jumpers in FIG. 6A, the arrangement of the plurality of electrodes and the arrangement of the plurality of jumpers corresponding to the plurality of electrodes may be easily performed inside the chuck plate 110.

Referring to FIG. 6B, a substrate support device 1C according to an embodiment may include electrodes of an arc shape in which each of the first electrode V1, the second electrode V2, and the third electrode V3 surrounding the center electrode V4 is partially disconnected, e.g., each of the first through third electrodes V1 through V3 may include a plurality of discrete portions that are spaced apart from each other along a circumference of the center electrode V4. For example, as illustrated in FIG. 6B, the spaces between the discrete portions may be aligned among the first through third electrodes V1 through V3 in the radial direction.

In detail, the first electrode V1 may include a plurality of first partial electrodes. For example, the first electrode V1 may include a first right side partial electrode VIR and a first left side partial electrode VIL. In other words, the first right side partial electrode VIR and the first left side partial electrode VIL may be included in the plurality of first partial electrodes. The first right side partial electrode VIR and the first left side partial electrode VIL may be arranged apart from each other with the center electrode V4 therebetween. The first right side partial electrode VIR may be on the right side with reference to the center electrode V4, and the first left side partial electrode VIL may be on the left side with reference to the center electrode V4. The first right side partial electrode VIR and the first left side partial electrode VIL may include electrodes of an arc shape (circular band shape) concentric with the center electrode V4 having a thickness. In other words, the first right side partial electrode VIR may be separated from the first left side partial electrode VIL.

For example, as illustrated in FIG. 6B, regions, where the first right side partial electrode VIR and the first left side partial electrode VIL are spaced apart and disconnected from each other, may be respectively positioned at an upper side and a lower side in the second horizontal direction (Y-axis direction) with reference to the center electrode V4, as viewed in a top view. As the number of disconnected portions (i.e., spaces between the discrete portions of the first electrode V1) of an arc shape that are portions of a concentric circle increases, the number of electrodes (i.e., the discrete portions) of an arc shape included in the first electrode V1 may increase. For example, as illustrated in FIG. 6B, there may be two disconnected portions (i.e., two spaces between the discrete portions), and the first right side partial electrode V1R and the first left side partial electrode V1L corresponding to an electrode of an arc shape may be provided (i.e., two discrete portions of an electrode). In another example, there may be three or more disconnected portions, and three or more electrodes corresponding to an electrode of an arc shape may be included in the first electrode V1. To apply the chucking force to the substrate W by dividing in a more detailed manner depending on a position, the number of electrodes included in the first electrode V1 may be selected and provided as necessary.

The first right side partial electrode V1R and the first left side partial electrode V1L may be connected to one end and the other end of the first jumper J21, respectively. In other words, the first right side partial electrode V1R and the first left side partial electrode V1L may be individually, e.g., independently, connected to jumpers and electrode wires, and individually, e.g., independently, receive power from the power control unit 200. The chucking forces generated in the first right side partial electrode V1R and the first left side partial electrode V1L may be different from each other. Accordingly, by applying chucking forces individually required by the first right side partial electrode V1R and the first left side partial electrode V1L, warpage of the substrate W may be suppressed, and at the same time, damage occurring on the lower surface, or a support surface, of the substrate W may be substantially reduced or prevented.

Similar to the first electrode V1, the second electrode V2 may include a second right side partial electrode V2R and a second left side partial electrode V2L. The third electrode V3 may include a third right side partial electrode V3R and a third left side partial electrode V3L. Descriptions of the second electrode V2 and the third electrode V3 are the same as descriptions of the first electrode V1, and thus are omitted.

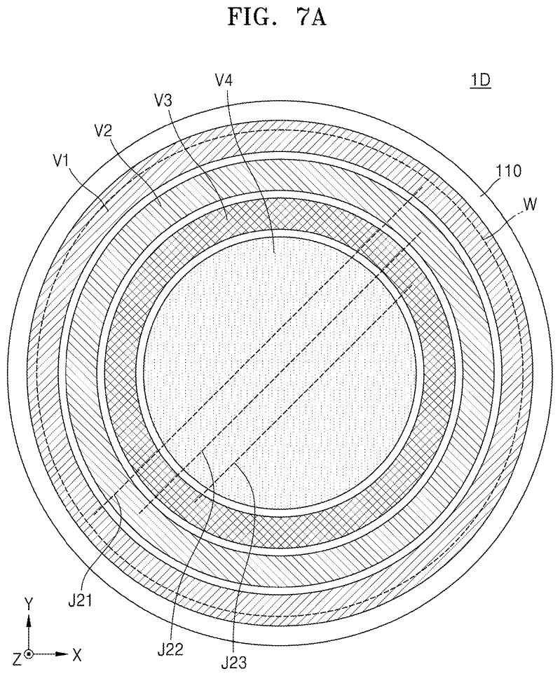

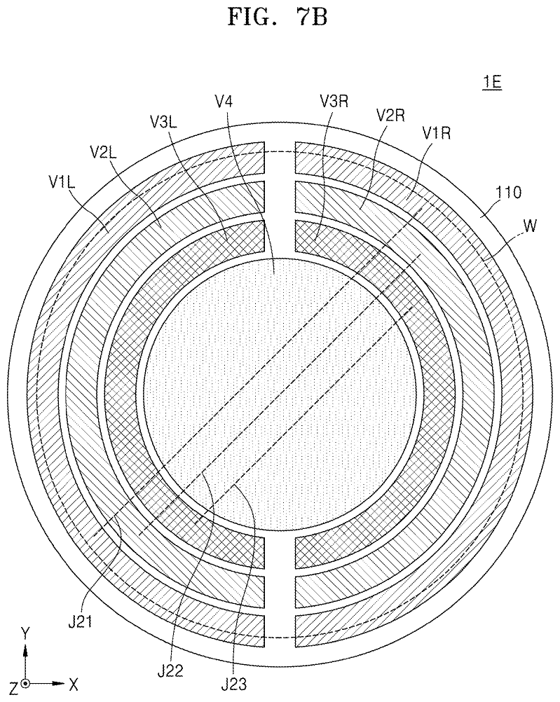

FIG. 7A is a plan view of a substrate support device 1D according to an embodiment. FIG. 7B is a plan view of a substrate support device 1E according to an embodiment. Duplicate descriptions given above are omitted.

Referring to FIG. 7A, in the substrate support device 1D according to an embodiment, the first jumper J21, the second jumper J22, and the third jumper J23 may be in parallel with each other, and arranged apart from each other. At the same time, the first connection jumper J21B, the second connection jumper J22B, and the third connection jumper J23B may be provided on a plane in parallel with the chuck plate 110.

Referring to FIG. 7B, in the substrate support device 1E according to an embodiment, the first jumper J21, the second jumper J22, and the third jumper J23 may be in parallel with each other, and arranged apart from each other. At the same time, the first connection jumper J21B, the second connection jumper J22B, and the third connection jumper J23B may be provided on a plane in parallel with the chuck plate 110. In addition, each of the first electrode V1, the second electrode V2, and the third electrode V3 surrounding the center electrode V4 may include an arc-shaped electrode (e.g., each having a plurality of discrete portions) centered around the center electrode V4.

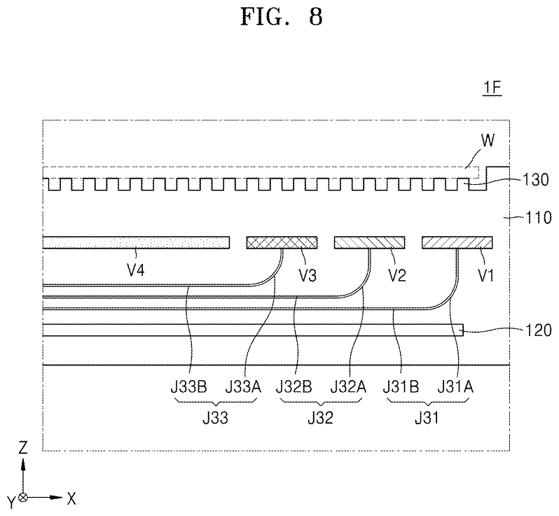

FIG. 8 is an enlarged cross-sectional view of a portion of a substrate support device 1F, according to an embodiment. Duplicate descriptions given above are omitted.

Referring to FIG. 8, a first jumper J31 may be connected to the first electrode V1. The first jumper J31 may include a first inclined jumper J31A and a first connection jumper J31B. The first inclined jumper J31A may electrically connect the bottom surface of the first electrode V1 to the first connection jumper J31B. The first connection jumper J31B may electrically connect one wire of the electrode wires 170 to the first inclined jumper J31A. The first inclined jumper J31A may have a shape of becoming closer to the upper surface of the chuck plate 110 away from the center of the chuck plate 110 in a radial direction of the chuck plate 110.

The first inclined jumper J31A may extend from the first connection jumper J31B to form a curve and may be connected to the first electrode V1. Similar to a portion of the first connection jumper J31B, a portion forming a curve in a jumper may be referred to as a curved unit. In example embodiments, the first connection jumper J31B may include a first curved unit protruding toward a lower portion of the outer diameter of the chuck plate 110. In other words, the center of curvature of the first curved unit may face the upper surface of the chuck plate 110 with reference to the jumper forming the first curved unit.

A second jumper J32 may be connected to the second electrode V2. The second jumper J32 may include a second inclined jumper J32A and a second connection jumper J32B. The second inclined jumper J32A may extend from the second connection jumper J32B to form a curve and may be connected to the second electrode V2. Similar to a portion of the second connection jumper J32B, a portion forming a curve in a jumper may be referred to as a curved unit. In example embodiments, the second connection jumper J32B may include a second curved unit protruding toward a lower portion of the outer diameter of the chuck plate 110. In other words, the center of curvature of the second curved unit may face the upper surface of the chuck plate 110 with reference to the jumper forming the first curved unit.

A third jumper J33 may be connected to the third electrode V3. The third jumper J33 may include a third inclined jumper J33A and a third connection jumper J33B. The third inclined jumper J33A may extend from the third connection jumper J33B to form a curve and may be connected to the third electrode V3. Similar to a portion of the third connection jumper J33B, a portion forming a curve in a jumper may be referred to as a curved unit. In example embodiments, the third connection jumper J33B may include a third curved unit protruding toward a lower portion of the outer diameter of the chuck plate 110. In other words, the center of curvature of the third curved unit may face the upper surface of the chuck plate 110 with reference to the jumper forming the first curved unit.

In the substrate support device 1F of FIG. 8, the first connection jumper J31B, the second connection jumper J32B, and the third connection jumper J33B may be provided on a plane in parallel with the chuck plate 110, but each of the first connection jumper J31B, the second connection jumper J32B, and the third connection jumper J33B may also be provided on a different plane.

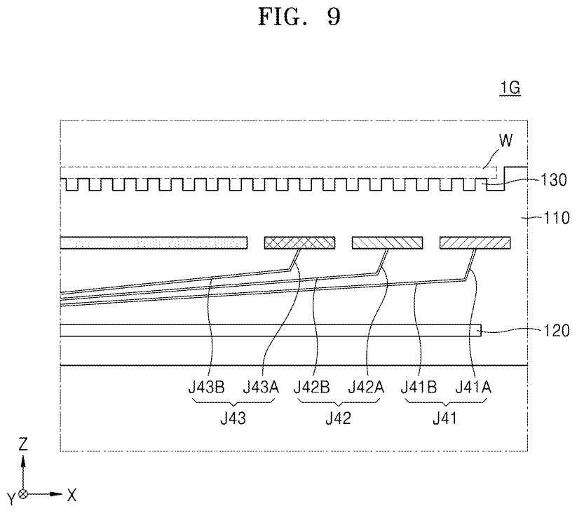

FIG. 9 is an enlarged cross-sectional view of a portion of a substrate support device 1G, according to an embodiment. Duplicate descriptions given above are omitted.

Referring to FIG. 9, a first jumper J41 may be connected to the first electrode V1. The first jumper J41 may include a first inclined jumper J41A and a first connection jumper J41B. The first inclined jumper J41A may electrically connect the bottom surface of the first electrode V1 to the first connection jumper J41B. The first connection jumper J41B may electrically connect one wire of the electrode wires 170 to the first inclined jumper J41A. The first inclined jumper J41A may extend in a line, and have a shape of becoming closer to the upper surface of the chuck plate 110 away from the center of the chuck plate 110 in a radial direction of the chuck plate 110. The first connection jumper J41B may extend in a line, and have a shape of becoming closer to the upper surface of the chuck plate 110 away from the center of the chuck plate 110 in a radial direction of the chuck plate 110.

The degree of becoming closer to the upper surface of the chuck plate 110 away from the center of the chuck plate 110 in a radial direction of the chuck plate 110 may be referred to as a slope. The slope of the first inclined jumper J41A may be greater than the slope of the first connection jumper J41B.

Similar to the first jumper J41, a shape of a second jumper J42 including a second inclined jumper J42A and a second connection jumper J42B, and a shape of a third jumper J43 including a third inclined jumper J43A and a third connection jumper J43B may also have the same shape as the shape of the first jumper J41 described above.

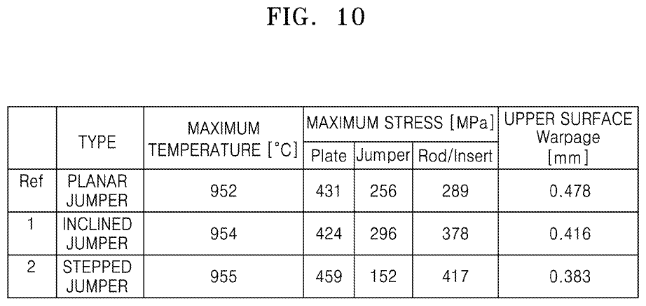

FIG. 10 illustrates simulation results of substrate support devices 1A and 1B, according to an embodiment.

Referring to the table in FIG. 10, a planar jumper refers to a jumper of a shape, in which the jumper extends in parallel with the upper surface of the chuck plate 110, and is vertically bent to be connected to an electrode. An inclined jumper of reference number 1 refers to inclined jumpers of the substrate support device 1A according to an embodiment described above. A stepped jumper of reference number 2 refers to stepped jumpers of the substrate support device 1B according to an embodiment described above.

In the substrate support devices according to embodiments, the chuck plate 110 may be heated, including the heater 120. For each jumper type, the maximum temperature, that the chuck plate 110 may reach, may be achieved in a similar range. However, the stress occurring in the chuck plate 110 may vary depending on the structure of the jumper.

Because the maximum stress occurring in the chuck plate 110 is in a range of 420 MPa to 460 MPa, there may be little significant difference depending on the jumper type. However, the maximum stress occurring around the jumper may be 152 MPa in the case of the stepped jumper, which is lower than the maximum stress of the planar jumper and inclined jumper. In addition, in the case of the inclined jumper and stepped jumper other than the planar jumper, the warpage caused by the temperature increase on the upper surface of the chuck plate 110 may be less than the warpage of the planar jumper, which has a conventional structure. The warpage occurring in the chuck plate 110 itself may reduce the durability of the chuck plate 110. By using the jumper structures of the substrate support devices 1A and 1B according to embodiment, warpage occurring in a chuck plate may be reduced. In addition, cracks occurring due to differences in thermal expansion rates between electrodes and jumpers, inside the chuck plate 110, may be reduced. Thus, it may be possible to enhance the reliability of the substrate W treatment process and the reliability of the substrate support devices by using the substrate support devices according to embodiments.

By way of summation and review, embodiments provide a method of increasing reliability of a substrate treatment process. That is, in the substrate support devices according to embodiments, cases, in which the electrode unit includes the first electrode V1, the second electrode V2, and the third electrode V3 surrounding the center electrode V4, are disclosed. The substrate support device according to embodiments are provided with an electrode unit including four or more electrodes of a concentric ring shape surrounding a center electrode, and four or more jumpers respectively corresponding to the four or more electrodes to provide independent control of each of the electrodes.

Example embodiments have been disclosed herein, and although specific terms are employed, they are used and are to be interpreted in a generic and descriptive sense only and not for purpose of limitation. In some instances, as would be apparent to one of ordinary skill in the art as of the filing of the present application, features, characteristics, and/or elements described in connection with a particular embodiment may be used singly or in combination with features, characteristics, and/or elements described in connection with other embodiments unless otherwise specifically indicated. Accordingly, it will be understood by those of skill in the art that various changes in form and details may be made without departing from the spirit and scope of the present invention as set forth in the following claims.

What is claimed is:

1. A substrate support device, comprising:
a chuck plate having a disk shape, the chuck plate being configured to support a substrate on an upper surface thereof;
a shaft connected to a center lower end of the chuck plate, the shaft being configured to support the chuck plate;
a heater inside the chuck plate;
an electrode structure on the heater inside the chuck plate;
a jumper inside the chuck plate, the jumper being between the electrode structure and the heater, and the jumper being electrically connected to the electrode structure to supply power to the electrode structure; and
a power controller connected to the jumper via a wire, the power controller being configured to supply and control power supplied to the electrode structure via the wire,
wherein:
the electrode structure includes a center electrode and a first electrode arranged in a ring shape around the center electrode, and
the jumper includes a first jumper connected to the first electrode, and a center jumper connected to the center electrode, the first jumper including:
a first connection jumper, and
a first inclined jumper electrically connecting the first connection jumper to the first electrode, the first inclined jumper extending away from a center of the chuck plate toward an upper surface of the chuck plate in a radial direction of the chuck plate.

2. The substrate support device as claimed in claim 1, wherein the first inclined jumper connects the first electrode to the first connection jumper, and an angle between the first inclined jumper and the first connection jumper is an obtuse angle.

3. The substrate support device as claimed in claim 1, wherein:
the electrode structure further includes a second electrode and a third electrode,
the jumper further includes a second jumper connected to the second electrode and a third jumper connected to the third electrode,
the second electrode and the third electrode are between the first electrode and the center electrode, and each of the first electrode, the second electrode, and the third electrode being arranged apart from each other in a concentric circular band shape from the center of the chuck plate,
the second jumper includes a second connection jumper, and a second inclined jumper electrically connecting the second connection jumper to the second electrode, the second inclined jumper extending away from the center of the chuck plate toward the upper surface of the chuck plate in the radial direction of the chuck plate, and
the third jumper includes a third connection jumper, and a third inclined jumper electrically connecting the third connection jumper to the third electrode, the third inclined jumper extending away from the center of the chuck plate toward the upper surface of the chuck plate in the radial direction of the chuck plate.

4. The substrate support device as claimed in claim 3, wherein:
an angle between the first inclined jumper and the first connection jumper is an obtuse angle,
an angle between the second inclined jumper and the second connection jumper is an obtuse angle, and
an angle between the third inclined jumper and the third connection jumper is an obtuse angle.

5. The substrate support device as claimed in claim 3, wherein the power controller is configured to control power supplied to each of the first electrode, the second electrode, the third electrode, and the center electrode.

6. The substrate support device as claimed in claim 5, wherein, with respect to a distance from the center of the chuck plate, the first electrode is in a range of 145 mm or more and 155 mm or less, the second electrode is in a range of 140 mm or more and less than 145 mm, and the third electrode is in a range of 135 mm or more and less than 140 mm.

7. The substrate support device as claimed in claim 5, wherein a radial distance to an outer diameter of the first electrode with respect to the center of the chuck plate is greater than a reference to an outer diameter of the substrate with respect to the center of the chuck plate.

8. The substrate support device as claimed in claim 3, wherein the first jumper, the second jumper, and the third jumper extend from the center of the chuck plate in the radial direction.

9. The substrate support device as claimed in claim 3, wherein the first connection jumper, the second connection jumper, and the third connection jumper are on a first surface in parallel with the upper surface of the chuck plate.

10. The substrate support device as claimed in claim 3, wherein the first connection jumper, the second connection jumper, and the third connection jumper are closer to the upper surface of the chuck plate away from the center of the chuck plate in the radial direction of the chuck plate.

11. The substrate support device as claimed in claim 1, wherein:
the first electrode includes a plurality of first partial electrodes,
each of the plurality of first partial electrodes has a concentric arc shape with respect to the center electrode, the plurality of first partial electrodes are spaced apart from each other and from the center electrode, and
the jumper is electrically connected to each of the plurality of first partial electrodes.

12. The substrate support device as claimed in claim 1, wherein:
the first inclined jumper includes a first curved unit, and
a center of curvature of the first curved unit faces the upper surface of the chuck plate with respect to a jumper constituting the first curved unit.

13. The substrate support device as claimed in claim 12, wherein:
the electrode structure further includes a second electrode and a third electrode,
the jumper further includes a second jumper connected to the second electrode and a third jumper connected to the third electrode,
the second electrode and the third electrode are between the first electrode and the center electrode, and each of the first electrode, the second electrode, and the third electrode are arranged apart from each other in a concentric circular band shape from the center of the chuck plate,
the second jumper includes a second connection jumper, and a second inclined jumper electrically connecting the second connection jumper to the second electrode and being closer to the upper surface of the chuck plate away from the center of the chuck plate in the radial direction of the chuck plate,
the third jumper includes a third connection jumper and a third inclined jumper electrically connecting the third connection jumper to the third electrode and being closer to the upper surface of the chuck plate away from the center of the chuck plate in the radial direction of the chuck plate,
the second inclined jumper includes a second curved unit and the third inclined jumper includes a third curved unit, and
a center of curvature of the second curved unit faces the upper surface of the chuck plate with respect to a jumper constituting the second curved unit, and a center of curvature of the third curved unit faces the upper surface of the chuck plate with respect to a jumper constituting the third curved unit.

14. The substrate support device as claimed in claim 1, wherein the chuck plate includes a material including aluminum nitride, and a temperature, at which a process of treating the substrate on the chuck plate is performed, is 400° C. to 800° C.

15. The substrate support device as claimed in claim 1, wherein the first inclined jumper includes three or more bent sections.

16. A substrate support device, comprising:
a chuck plate having a disk shape, the chuck plate being configured to support a substrate on an upper surface thereof;
a shaft connected to a center lower end of the chuck plate, the shaft being configured to support the chuck plate;
a heater inside the chuck plate;
an electrode structure on the heater inside the chuck plate;
a jumper inside the chuck plate, the jumper being between the electrode structure and the heater, and the jumper being electrically connected to the electrode structure to supply power; and
a power controller connected to the jumper via a wire, the power controller being configured to supply and control power supplied to the electrode structure via the wire,
wherein the electrode structure includes a first electrode, N additional electrodes (N is a natural number equal to or greater than 3), and a center electrode, which face from a periphery of the chuck plate to a center of the chuck plate,
wherein the jumper includes a first jumper connected to the first electrode, N jumpers respectively connected to the N additional electrodes, and a center jumper connected to the center electrode,
wherein the N additional electrodes are between the first electrode and the center electrode, and the first electrode and the N additional electrodes are arranged apart from each other in a concentric circular band shape from the center of the chuck plate,
wherein the first jumper includes a first connection jumper, and a first inclined jumper electrically connecting the first connection jumper to the first electrode and being closer to the upper surface of the chuck plate away from the center of the chuck plate in a radial direction of the chuck plate, and
wherein the N jumpers respectively include N connection jumpers and N inclined jumpers respectively and electrically connecting the N connection jumpers to the N additional electrodes and being closer to the upper surface of the chuck plate away from the center of the chuck plate in the radial direction of the chuck plate.

17. The substrate support device as claimed in claim 16, wherein:
the first inclined jumper connects the first electrode to the first connection jumper, and an angle between the first inclined jumper and the first connection jumper is an obtuse angle, and
the first through Nth inclined jumpers respectively connect the first through Nth additional electrodes to the first through Nth connection jumpers, and respective angles between the first through Nth inclined jumpers and the first through Nth connection jumpers are obtuse angles.

18. The substrate support device as claimed in claim 16, wherein:
the first inclined jumper includes a first curved unit, and the N inclined jumpers respectively include N curved units, and
a center of curvature of the first curved unit faces the center of the chuck plate with respect to a jumper constituting the first curved unit, and centers of curvature of the N curved units face the center of the chuck plate with respect to jumpers constituting the N curved unit.

19. The substrate support device as claimed in claim 16, wherein the first inclined jumper includes three or more bent sections, and each of the N inclined jumpers includes three or more bent sections.

20. A substrate support device, comprising:
a chuck plate having a disk shape, the chuck plate being configured to support a substrate on an upper surface thereof;
a shaft connected to a center lower end of the chuck plate, the shaft being configured to support the chuck plate;
a heater inside the chuck plate;
an electrode structure on the heater inside the chuck plate;
a jumper inside the chuck plate, the jumper being between the electrode structure and the heater, and the jumper being electrically connected to the electrode structure to supply power; and
a power controller connected to the jumper via a wire, the power controller being configured to supply and control power supplied to the electrode structure via the wire,
wherein the electrode structure includes a first electrode, a second electrode, a third electrode, and a center electrode, which face from a periphery of the chuck plate to a center of the chuck plate,
wherein the jumper includes a first jumper connected to the first electrode, a second jumper connected to the second electrode, a third jumper connected to the third electrode, and a center jumper connected to the center electrode,
wherein the second electrode and the third electrode are between the first electrode and the center electrode, and the first electrode, the second electrode, and the third electrode are arranged apart from each other in a concentric circular band shape from the center of the chuck plate,
wherein the first jumper includes a first connection jumper and a first inclined jumper electrically connecting the first connection jumper to the first electrode and being closer to the upper surface of the chuck plate away from the center of the chuck plate in a radial direction of the chuck plate,
wherein the second jumper includes a second connection jumper and a second inclined jumper electrically connecting the second connection jumper to the second electrode and being closer to the upper surface of the chuck plate away from the center of the chuck plate in the radial direction of the chuck plate,
wherein the third jumper includes a third connection jumper and a third inclined jumper electrically connecting the third connection jumper to the third electrode and being closer to the upper surface of the chuck plate away from the center of the chuck plate in a radial direction of the chuck plate,
wherein the first connection jumper, the second connection jumper, and the third connection jumper are on a flat surface in parallel with the upper surface of the chuck plate,
wherein an angle between the first inclined jumper and the first connection jumper is an obtuse angle,
wherein an angle between the second inclined jumper and the second connection jumper is an obtuse angle,
wherein an angle between the third inclined jumper and the third connection jumper is an obtuse angle,
wherein the power controller is configured to control power supplied to each of the first electrode, the second electrode, the third electrode, and the center electrode, and
wherein, with respect to a distance from the center of the chuck plate, the first electrode is in a range of 145 mm to 155 mm, the second electrode is in a range of 140 mm to 145 mm, and the third electrode is in a range of 135 mm to less than 140 mm.
